(19) United States
(12) Patent Application Publication
(10) Pub. No.: US 2024/0407154 A1
(43) Pub. Date: Dec. 5, 2024

(54) DIGIT LINE / CELL PLATE ISOLATION

(71) Applicant: Micron Technology, Inc., Boise, ID (US)

(72) Inventors: Albert Daen Liao, Boise, ID (US); Ting Zhao, Boise, ID (US); Cheng Li, Boise, ID (US); Ruijing Ge, Boise, ID (US); Matthew Jacob Jerry, Boise, ID (US); David A. Daycock, Boise, ID (US); Kolya Yastrebenetsky, Boise, ID (US); Kamal M. Karda, Boise, ID (US)

(21) Appl. No.: 18/677,457

(22) Filed: May 29, 2024

Related U.S. Application Data
(60) Provisional application No. 63/469,702, filed on May 30, 2023.

(51) Int. Cl. H10B 12/00

(52) U.S. Cl. CPC H10B 12/482; H10B 12/02

(57) ABSTRACT

A variety of applications can include an apparatus having a memory device including digit lines isolated from each other by filling an area directly under the digit line with a dielectric material. The dielectric material can be any insulating material such as oxides or nitrides. The provision of the area directly under each digit line can be accomplished without etching out an entire layer of epitaxially grown regions for the memory cells vertically stacked in a three-dimensional array. In a three-dimensional DRAM, metal plates for capacitors can be isolated in a manner similar to the isolation of digit lines. Such processing can be scalable, which may allow for a three-dimensional DRAM to have hundreds memory cell tiers.

### PRIORITY APPLICATION

This application claims the benefit of priority to U.S. Provisional Application Ser. No. 63/469,702, filed May 30, 2023, which is incorporated herein by reference in its entirety.

### FIELD OF THE DISCLOSURE

Embodiments of the disclosure relate generally to integrated circuits and, more specifically, to three-dimensional memory devices having isolated digit lines or isolated metal plates and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, digit lines and cell plates in 3D-DRAMS for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIGS. 1-5 are cross-sectional representations illustrating a fabrication procedure of forming a memory device, in accordance with various embodiments.

FIG. 6 illustrates a three-dimensional representation of a structure for a memory device, after digit line processing, in accordance with various embodiments.

FIG. 7 shows a three-dimensional representation of a structure illustrating a metal plate coupled to tiers of memory cells of an array of a memory device, in accordance with various embodiments.

FIG. 8 is a flow diagram of features of a method of forming a memory device, in accordance with various embodiments.

FIG. 9 is a flow diagram of features of an example method of forming a memory device, in accordance with various embodiments.

FIG. 10 is a schematic of circuitry of an example dynamic random-access memory device that can include an architecture having a memory array with digit line isolation or cell plate isolation, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In some conventional 3D-DRAMs, digit lines for writing and reading data extend vertically. An individual vertical digit line is horizontally separated from adjacent digit lines by insulator regions. These insulator regions provide isolation such that there is no direct path to short adjacent digit lines. Such isolation is also to be provided to metal plates for capacitors of memory cells. Adjacent digit lines and metal plates should not be tied together by a path through the substrate on which these components are positioned. With the substrate being a silicon (Si) substrate, a path around the insulator regions through the Si substrate could tie adjacent digital lines together or tie adjacent metal plates together. One approach to isolate adjacent digital lines or isolate metal plates includes filling a level below the levels of memory cells of the 3D-DRAM on the memory die with an oxide. With the memory cells formed epitaxially in a tiered structure with a memory cell positioned above another memory cell, the oxide fill is performed by forming a trench in a material stack for the memory cells and removing material via the trench to form an opening below the material stack. A set of etching procedures is used to form the opening. This opening is then filled with the oxide. However, this approach to producing an oxide level between digit lines/metal plates and a Si substrate is limited in the number of tiers of memory cells that can support the procedure of generating a horizontal opening via a trench. Such a method has been limited to less than ten tiers for an array, in which the method can isolate the entire array from the substrate to isolate digit lines, by etching out an entire layer of epitaxially grown silicon and refilling the entire layer with oxide. For many stacked layers greater than or equal to twenty tiers, this procedure of etching out an entire layer of epitaxially grown silicon will not work since it is not possible to fill the bottom horizontal opening through a small critical dimension (CD) and high aspect ratio created by these high numbers of tiers. Hence, this fabrication procedure is not a scalable process flow.

In various embodiments, a process flow can be implemented to isolate digit lines and plates from a substrate on which the digit lines and the plates are arranged for an array of memory cells, where the process flow can be performed without etching out an entire layer of epitaxially grown regions for the memory cells. This process flow isolates digit lines from each other and associated plates from the substrate by filling the area directly under the digit lines and the plate, to be formed, with an insulating dielectric. The insulating dielectric can be, but is not limited to, an oxide. The insulating dielectric can be formed on an insulating nitride region on the substrate.

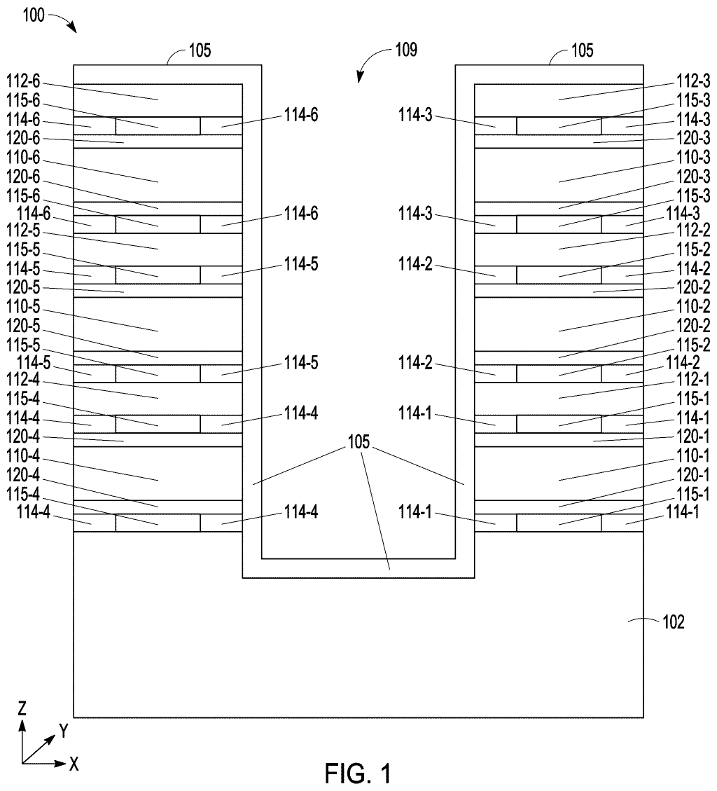

FIGS. 1-5 are cross-sectional representations illustrating a fabrication procedure of forming a memory device. This fabrication procedure or a similar fabrication procedure can isolate digit lines from each other and associated plates from the substrate by filling the area directly under the digit lines and the plate, to be formed, with an insulating dielectric.

FIG. 1 shows a cross-sectional representation of a structure 100 that has been formed into two stacks of memory cells about a trench 109 above a substrate 102. Substrate 102 can be, but is not limited to, a silicon-based substrate, and the memory cells can be, but are not limited to, silicon-based memory cells. Though each of the two stacks of memory cells are shown as three tiers of memory cells, structure 100 or a similar structure can include more than three tiers such as, but not limited to, eighty or more tiers. A memory cell can include an access transistor coupled to an assigned capacitor. A capacitor for each memory cell (not shown in FIG. 1) is positioned on the same tier as its associated access transistor of the memory cell, to the right on one stack of memory cells and to the left of the other stack of memory cells in the view of FIG. 1.

One stack can include a first memory cell having an active region 110-1 with a gate 115-1 wrapped around active region 110-1 and separated from active region 110-1 by a gate dielectric 120-1, a second memory cell having an active region 110-2 with a gate 115-2 wrapped around active region 110-2 and separated from active region 110-2 by a gate dielectric 120-2, and a third memory cell having an active region 110-3 with a gate 115-3 wrapped around active region 110-3 and separated from active region 110-3 by a gate dielectric 120-3. The first memory cell formed in this stack can be separated from the second memory cell of this stack by an inter-tier dielectric (ITD) 112-1. The second memory cell formed in this stack can be separated from the third memory cell of this stack by an ITD 112-2. An ITD 112-3 has been positioned above and contacting the third memory cell.

The other stack can include a fourth memory cell having an active region 110-4 with a gate 115-4 wrapped around active region 110-4 and separated from active region 110-4 by a gate dielectric 120-4, a fifth memory cell having an active region 110-5 with a gate 115-5 wrapped around active region 110-5 and separated from active region 110-5 by a gate dielectric 120-5, and a sixth memory cell having an active region 110-6 with a gate 115-6 wrapped around active region 110-6 and separated from active region 110-6 by a gate dielectric 120-6. The fourth memory cell that is in this other stack can be separated from the fifth memory cell in this other stack by an ITD 112-4. The fifth memory cell that is in this other stack can be separated from the sixth memory cell that is in this other stack by an ITD 112-5. An ITD 112-6 has been positioned above and contacting the fifth memory cell.

Each of active regions 110-1, 110-2, 110-3, 110-4, 110-5, and 110-6 can include a source, a drain, and channel coupled by a channel structure. Each of gate dielectrics 120-1, 120-2, 120-3, 120-4, 120-5, and 120-6 can be a gate oxide such as silicon oxide or a high-k dielectric. A high-k dielectric is a dielectric having a dielectric constant greater than that of silicon dioxide. Each of ITDs 112-1, 112-2, 112-3, 112-4, 112-5, and 112-6 can include, but is not limited to, an oxide such as a silicon oxide. Adjacent to and contacting gates 115-1, 115-2, 115-3, 115-4, 115-5, and 115-6 are dielectric regions 114-1, 114-2, 114-3, 114-4, 114-5, and 114-6, respectively, such as, but not limited to, silicon nitride regions.

Trench 109 is defined by a liner 105 that has been formed on the walls of trench 109 and has been formed on substrate 102 at the bottom of trench 109. Liner 105 has also been formed on a surface above the two stacks of memory cells. Liner 105 can be, but is not limited to, an insulating nitride such as silicon nitride.

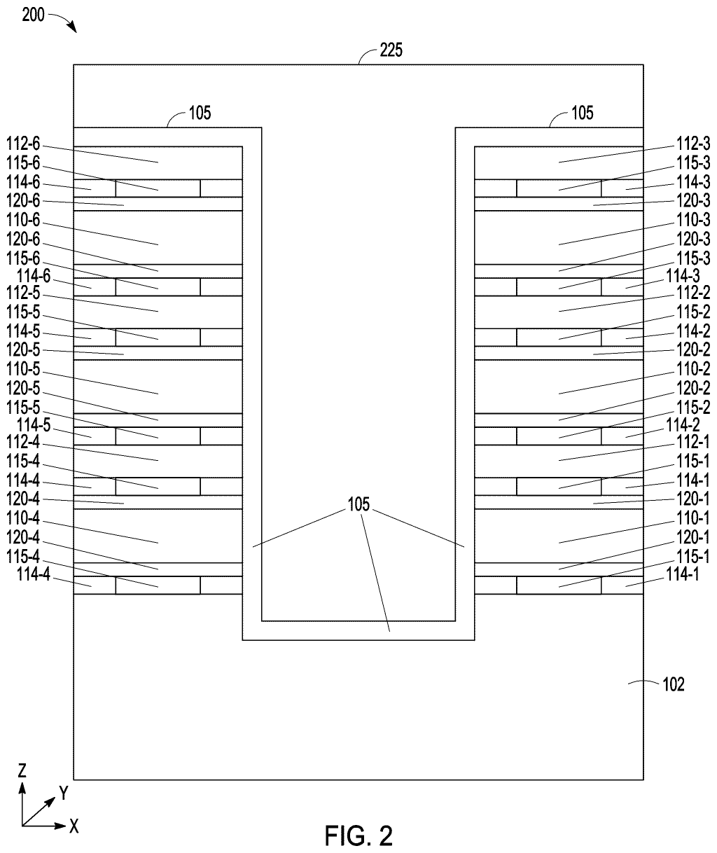

FIG. 2 shows a cross-sectional representation of a structure 200 that has been formed from processing structure 100 of FIG. 1. Trench 109 of structure 100 has been filled with a dielectric 225. Dielectric 225 has been formed on liner 105, including on liner 105 that has been formed on the surface above the two stacks of memory cells. Dielectric 225 can be, but is not limited to, an oxide such as a spin-on dielectric (SOD). After forming dielectric 225, dielectric 225 can be densified. Dielectric 225 can be an insulating carbon composition.

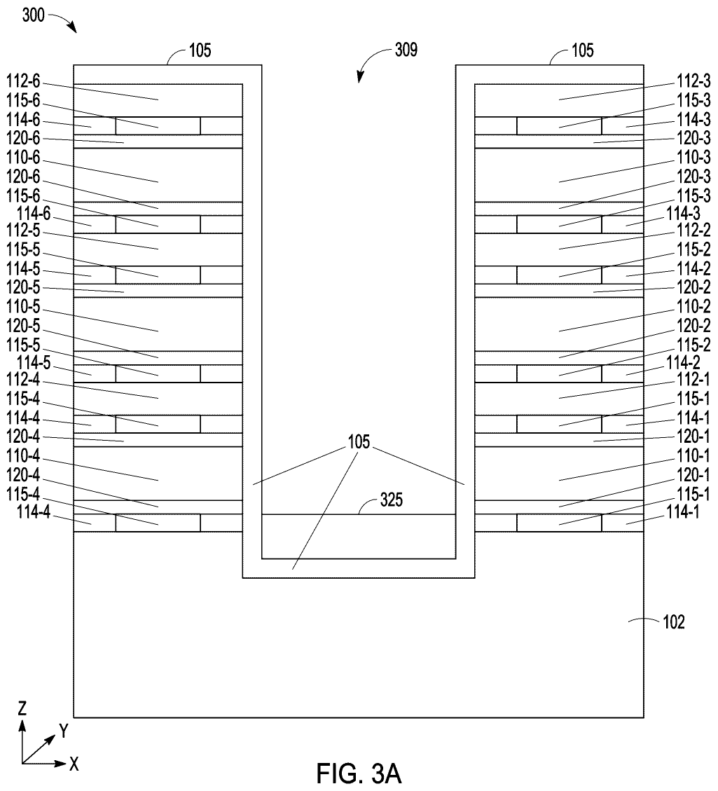

FIG. 3A shows a cross-sectional representation of a structure 300 that has been formed from processing structure 200 of FIG. 2. Dielectric 225 has been removed to a level below a top surface of the memory cells, leaving a dielectric portion 325 on liner 105 formed at the bottom of trench 109. This removal has formed an opening 309 that exposes the vertical sidewalls of liner 105 and the top surface liner 105. An wet etchant can be performed to selectively remove the portions of dielectric 225, leaving the liner 105. Two dummy layers (not shown) can be structured at the bottom of the two stacks of memory cells. These two dummy layers can provide a margin of appropriately 160 nm of variation across substrate 102, where substrate 102 can be a wafer. FIG. 3B is a cross-sectional representation of a structure 300-1 similar to structure 300 that has been formed from processing a structure similar to structure 200 of FIG. 2 having dummy layers 304-1 and 304-2.

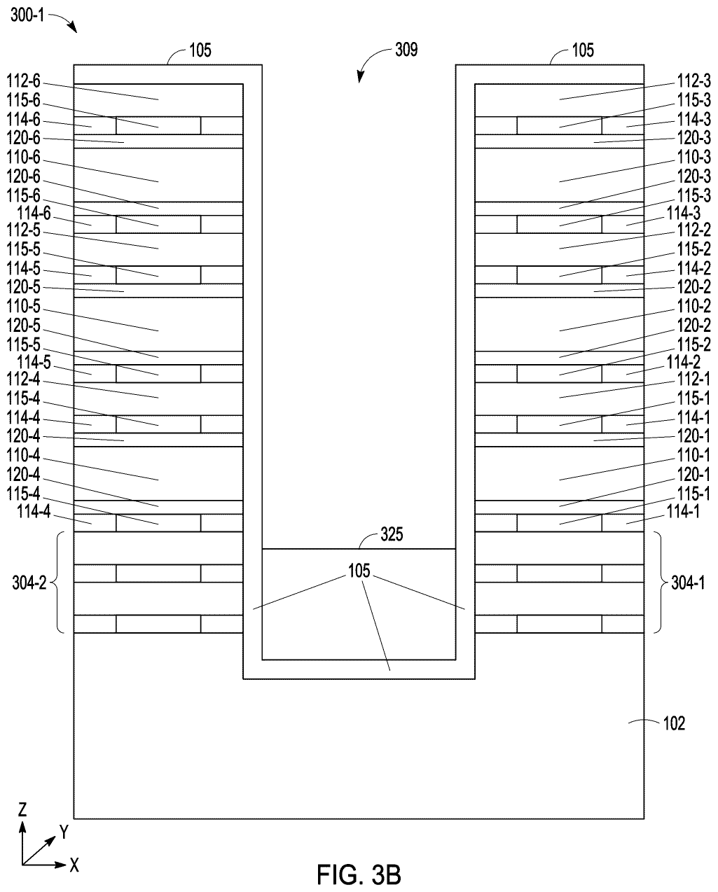

FIG. 4 shows a cross-sectional representation of a structure 400 that has been formed from processing structure 300 of FIG. 3A or structure 300-1 of FIG. 3B. Vertical portions of liner 105 have been removed above dielectric portion 325 on liner 105 and liner 105 has been removed from the surface above the two sets of memory cells. This removal has formed an extended opening 409 in which dielectric portion 325 on liner 105 and the surface above the two sets of memory cells are exposed for further processing. In addition, regions adjacent to liner 105 and dielectric portion 325 have been exposed.

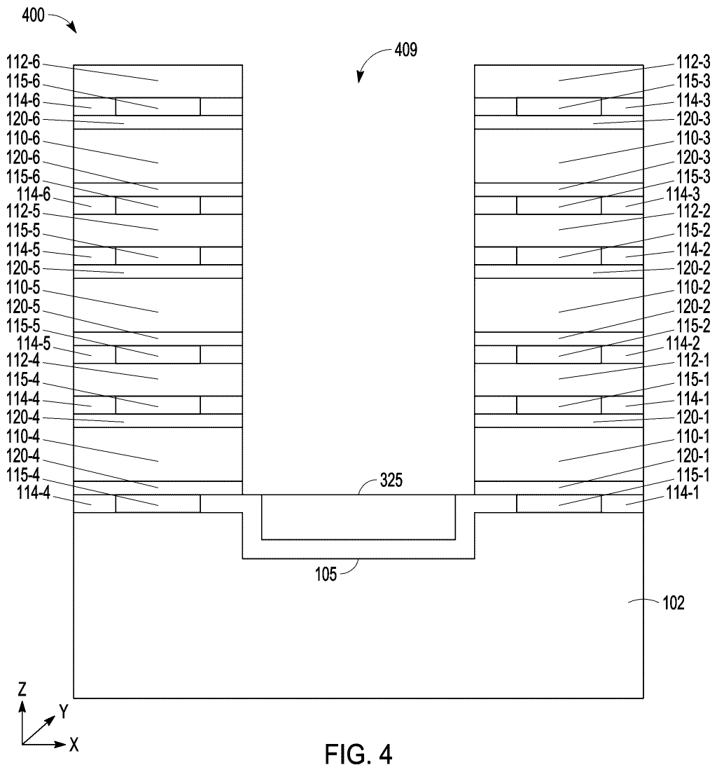

FIG. 5 shows a cross-sectional representation of a structure 500 that has been formed from processing structure 400 of FIG. 4. A metal has been formed on the sidewalls of opening 409 of structure 400 and on the surface above the two sets of memory cells from which liner 105 was removed. The metal can be deposited to form a metal digit line (DL) 530. Opening 409 of structure 400 has been reduced to opening 509. DL 530 is formed coupled to the memory cells of the two stacks.

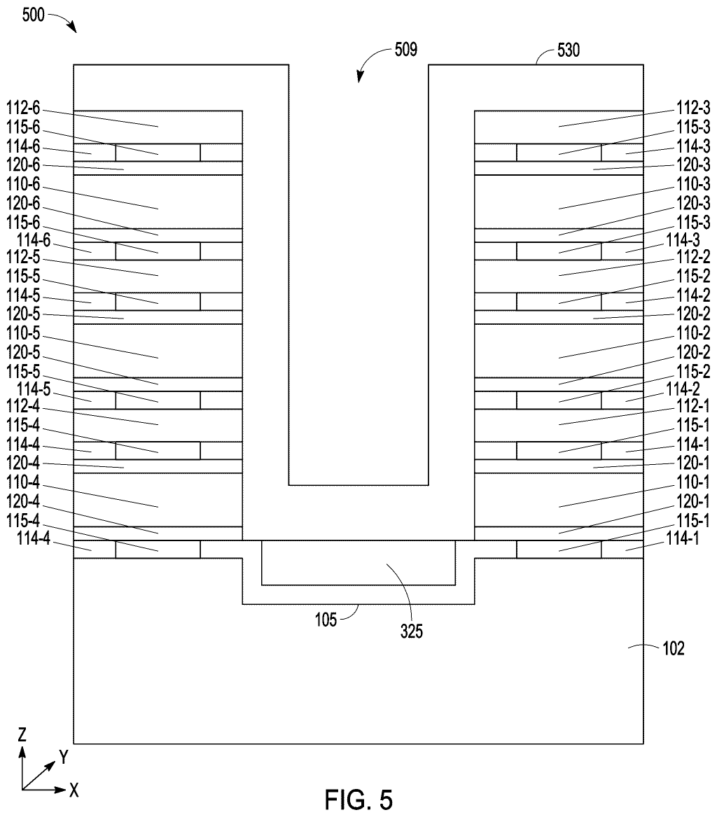

FIG. 6 illustrates a 3D representation of a structure 600 after DL processing, illustrating multiple DLs coupled to different sets of memory cells formed beginning with a trench such as trench 109 of FIG. 1. Each DL is coupled to memory cells of two stacks about a trench 609 above a substrate.

FIG. 6 shows a view 601 of structure 600, showing multiple DLs 610-1, 610-2, 610-3, 610-4, 610-5, and 610-6 that are coupled to the set of memory cells on the left side of trench 609. Also illustrated are bottom portions 611-1, 611-2, 611-3, 611-4, 611-5, and 611-6 of DLs 610-1, 610-2, 610-3, 610-4, 610-5, and 610-6, respectively, that connect these portions of DLs to portions of the DLs coupled with the set of memory cells on the right of trench 609. An insulator 613-1 separates DL 610-1 from regions of structure 600 to the left of DL 610-1 in view 601. DL 610-1 is separated from DL 610-2 by an insulator 613-2. DL 610-2 is separated from DL 610-3 by an insulator 613-3. DL 610-3 is separated from DL 610-4 by an insulator 613-4. DL 610-4 is separated from DL 610-5 by an insulator 613-5. DL 610-5 is separated from DL 610-6 by an insulator 613-6. An insulator 613-7 separates DL 610-6 from regions of structure 600 to the right of DL 610-6 in view 606. Though the right side of FIG. 6 shows six DLs, structure 600 or a structure similar to structure 600 can have significantly more than six DLs.

Using the process flow of FIGS. 1-5 or similar process, each of DLs 610-1, 610-2, 610-3, 610-4, 610-5, and 610-6 can be formed on a dielectric 625 disposed for the individual DLs. Dielectric 625 has been formed on a liner 605 used in the formation of dielectric 625, where liner 605 is positioned on substrate 602. With structure 600 being the result of the process flow of FIGS. 1-5, substrate 602 is substrate 102 and, for each of DLs 610-1, 610-2, 610-3, 610-4, 610-5, and 610-6, dielectric 625 can be dielectric portion 325 for the one DL illustrated in FIGS. 1-5, with liner 605 formed with the formation of liner 105 for the one DL illustrated in FIGS. 1-5.

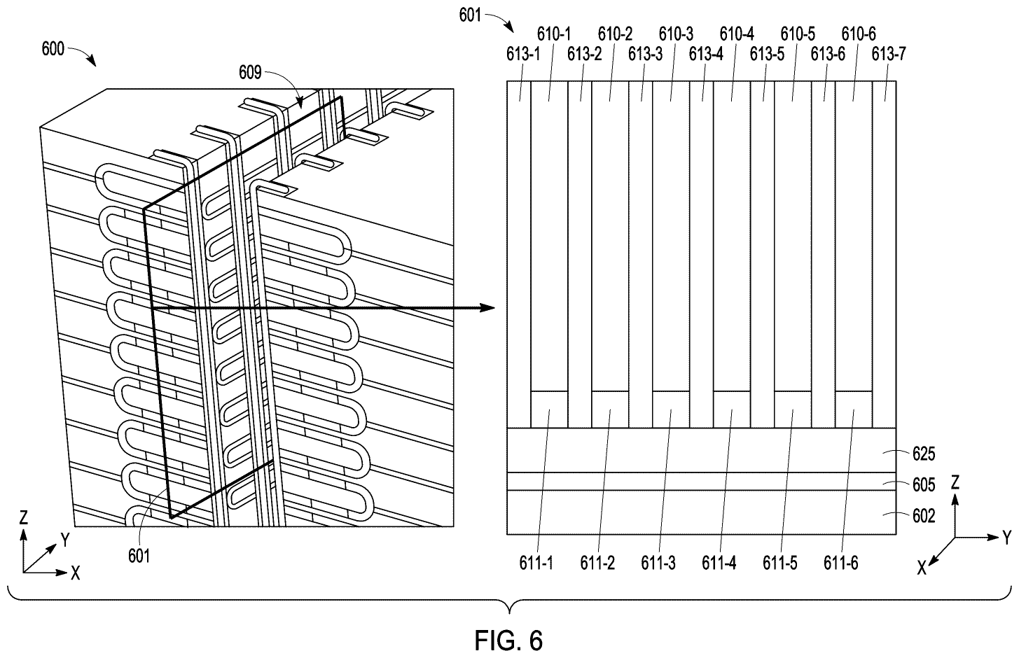

FIG. 7 shows a 3D representation of a structure 700 illustrating a metal plate 735 coupled to memory cells of an array of a memory device. The memory cells include sets 727 of access transistors shown along the x-direction that are coupled to a digit line 730, where each access transistor is coupled to a capacitor. Two portions of digit line 730 are separated from each other by a dielectric region 711 that is coupled to a top dielectric region 721. In the x-directional cross-section shown, the set 727 on the right of digit line 730 is coupled to a set 729 of capacitors, which can be coupled to a metal plate 735. Digit line 730 can be formed using a fabrication procedure similar to or identical to the fabrication procedures associated with FIGS. 1-6. Digit line 730 has been formed on a dielectric 725 that was formed on a liner 705 on a substrate 702. Digit line 730 extends vertically from dielectric 725. Substrate 702 can be a silicon-based substrate. Digit line 730 has been formed as part of a process flow without etching out an entire layer of epitaxially grown regions for the memory cells. This process flow isolates digit line 730 from substrate 702 by filling the area directly under digit line 730 with dielectric 725. Dielectric 725 can be, but is not limited to, an oxide, such as a SOD, or a carbon composition. Liner 705, used in positioning dielectric 725, can be an insulating nitride liner such as, but not limited to, silicon nitride.

In the cross-section in the y-direction shown in FIG. 7, metal plate 735 can couple to another set 729 of capacitors. Each of the capacitors of this other set 729 can couple to access transistors, not shown in this view, forming sets of memory cells that can extend in the x-direction. Each set of memory cells in the x-direction can be separated from an adjacent set of memory cells by a dielectric region 713. In each set of memory cells there are memory cells stacked in the vertical direction (2-direction), formed as part of tiers of memory cells. Structure 700 illustrates a structure resulting from a process flow similar or identical to the process flow associated with FIGS. 1-6. Such a process flow can be applied to a number of sets of memory cells to form metal plate 735 with metal plate 735 arranged opposite a digit line 730 with respect to the memory cells, where metal plate 735 can be structured vertically coupled to the set of memory cells. Metal plate 735 has been formed on a dielectric 725 that was formed on a liner 705 on a substrate 702. Substrate 702 can be a silicon-based substrate. Metal plate 735 has been formed without etching out an entire layer of epitaxially grown regions for the memory cells. This process flow isolates metal plate 735 from substrate 702 by filling the area directly under the metal plate with dielectric 725. Dielectric 725 can be, but is not limited to, an oxide, such as a SOD, or a carbon composition. Liner 705, used in positioning dielectric 725, can be an insulating nitride liner such as, but not limited to, silicon nitride.

As shown in FIG. 7, structure 700 includes memory cells having access transistors coupled to capacitors oriented in a horizontal direction relative to substrate. Each of the horizontally oriented memory cells can be arranged in a vertical stack, forming tiers of memory cells. The inset of FIG. 7 shows a memory cell 727-2 among a stack of the set of memory cells formed by set 727 of access transistors and set 729 of capacitors. Memory cell 727-1 includes an active region 710-1 including a channel structure and associated source/drain regions. A gate 715-1 is wrapped around active region 710-1 and separated from active region 710-1 by a gate dielectric 720-1. Active region 710-1, gate 715-1, and gate dielectric 720-1 can be structured similar to the active regions, gates, and gate dielectrics of FIG. 1 with appropriate electrical insulating regions about active region 710-1, gate 715-1, and gate dielectric 720-1. A source/drain region of active region 710-1 is coupled to an electrode 724-1 of a capacitor 729-1. Electrode 724-1 is separated from another electrode 728-1 by a capacitor dielectric 726-1. Electrode 728-1 of capacitor 729-1 is coupled to metal plate 735. Active region 710-1 can be a silicon region, a silicon-based region, or a region of other semiconductor material appropriate for an access transistor. Gate dielectric 720-1 can be an oxide, such as but not limited to, silicon oxide or a high-k dielectric. Gate 715-1 can be a metal gate or a polysilicon gate. Electrodes 724-1 and 728-1 can be metal electrodes or other appropriate conductive electrodes and capacitor dielectric 726-1 can be an oxide, such as but not limited to, silicon oxide or a high-k dielectric.

Various deposition techniques for components of structures in the process flows discussed above or similar structures and process flows can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Etching procedures can include, but are not limited to, wet etching, dry etching, and atomic layer etching deposition, among others.

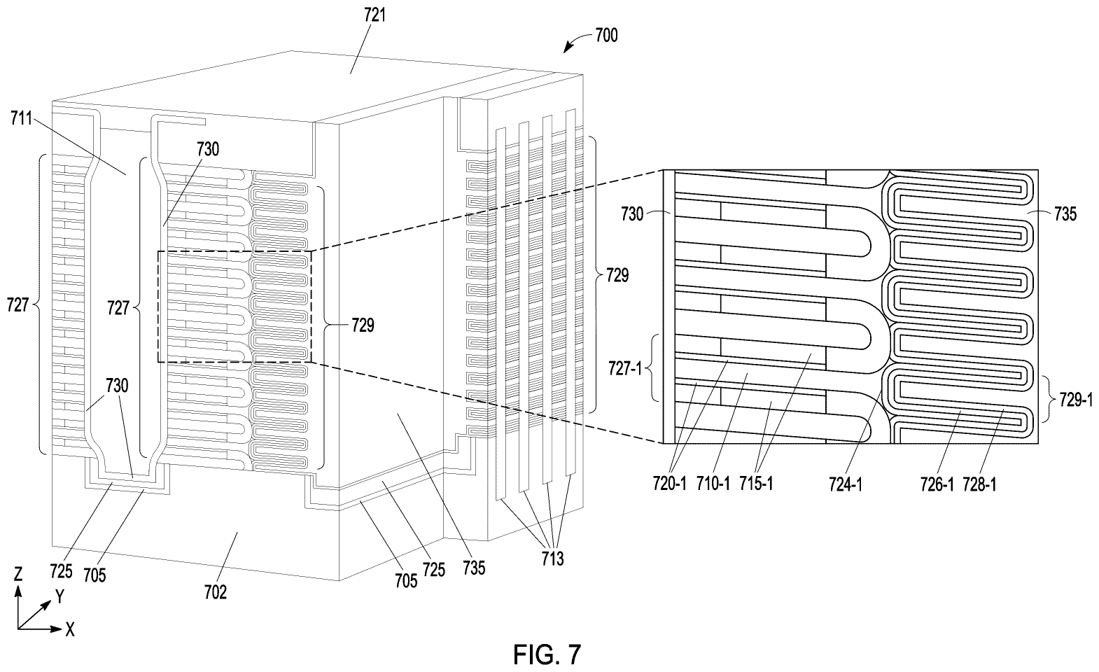

FIG. 8 is a flow diagram of a method 800 of forming a memory device. The fabrication can provide for isolation of digit lines or metal plates from a substrate of the memory device. The memory device can be a 3D-DRAM, for example. At 810, a liner is formed in a trench between formed memory cells, where the liner is a dielectric. The liner is formed on a bottom of the trench and along sidewalls of the trench and provides protection to the formed memory cells for digit line processing. At 820, an insulator material is formed on the liner, filling the trench. At 830, the insulator material is removed to a level below a top surface of the memory cells. A portion of the insulator material is left on the liner at the bottom of the trench and an opening is formed that exposes the liner on the sidewalls. At 840, the liner is removed from the sidewalls. At 850, conductive material for a digit line is formed on the portion of the insulator material at the bottom of the trench and along the sidewalls. The conductive material can include one or more metals. The one or more metals can include one or more of tungsten, ruthenium, titanium, titanium nitride, tungsten nitride, or combinations thereof.

Variations of method 800 or methods similar to method 800 can include a number of different embodiments that may be combined depending on the application of such methods and/or the architecture of systems including a memory device in which such methods are implemented. Such methods can include removing the insulator material to a top level of one or more dummy memory cell layers, where the one or more dummy memory cell layers are positioned below the memory cells stacked vertically. Variations can include forming one or more metals for the digit line on a dielectric region above the memory cells. Variations can include forming a metal for a metal plate to memory cells opposite the conductive material for the digit line. Variations can include removing the insulator material by applying a wet etch, exposing the liner on the sidewalls.

Variations of method 800 or methods similar to method 800 can include the liner being a nitride liner such as, but not limited to, silicon nitride. Variations can include the insulator material being an oxide. Variations can include the insulator material having a dielectric constant equal to or less than that of silicon dioxide. Variations can include the insulator material being a spin-on dielectric. The spin-on dielectric can be densified. Variations can include the insulator material being an insulating carbon composition.

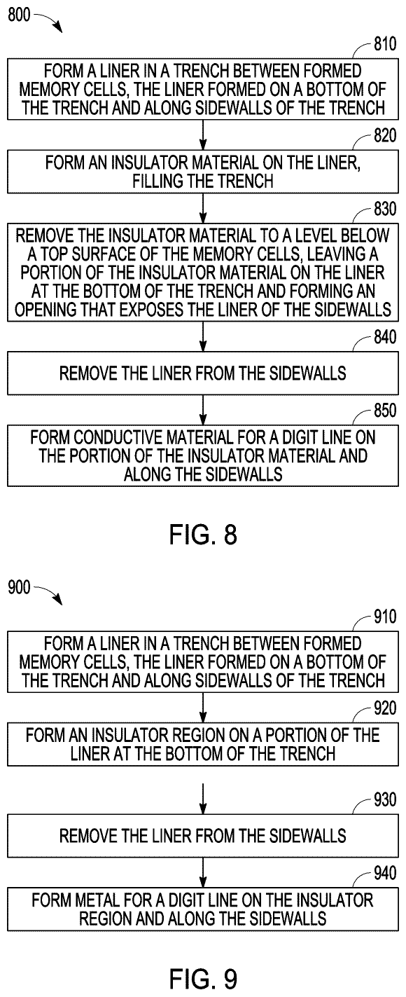

FIG. 9 is a flow diagram of a method of forming a memory device. The fabrication can provide for isolation of digit lines or metal plates from a substrate of the memory device. The memory device can be a 3D-DRAM, for example. At 910, a liner is formed in a trench between formed memory cells. The liner provides a dielectric component that protects the formed memory cells for the digit line processing. The formed memory cells are positioned in tiers with a memory cell of a tier positioned vertically above a directly adjacent memory tier in a lower tier. The liner is formed on a bottom of the trench and along sidewalls of the trench. At 920, an insulator region is formed on a portion of the liner at the bottom of the trench. At 930, the liner is removed from the sidewalls. At 940, metal is formed for a digit line on the insulator region and along the sidewalls. The metal can include one or more of tungsten, ruthenium, titanium, titanium nitride, tungsten nitride, or combinations thereof.

Variations of method 900 or methods similar to method 900 can include a number of different embodiments that may be combined depending on the application of such methods and/or the architecture of systems including a memory device in which such methods are implemented. Such methods can include forming the insulator region to include seeded growth from the portion of the liner at the bottom of the trench. Variations can include forming a second metal for a metal plate to memory cells opposite the metal for the digit line.

In various embodiments, a memory device can comprise an array of memory cells, where the array includes sets of memory cells arranged vertically, and a digit line structured vertically and coupled to a set of the sets of memory cells arranged vertically. The digit line is positioned on and contacts an insulator material, where a top level of the insulator material is below a bottom level of the memory cells of the set corresponding to the digit line. The digit line is a conductive line that can include, but is not limited to, one or more metals. The one or more metals can include one or more of tungsten, ruthenium, titanium, titanium nitride, tungsten nitride, or combinations thereof.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the set of memory cells arranged vertically coupled to the digit line having eighty or more tiers of memory cells arranged vertically. Variations of such memory devices can include the memory cells of the set of memory cells arranged vertically coupled to the digit line being positioned on one or more levels of dummy cells. The one or more levels of dummy cells can provide a margin of approximately 160 nm of variation across a memory die on which the sets of memory cells are positioned.

Variations of such a memory device and its features can include the insulator material having a dielectric constant equal to or less than that of silicon dioxide. Variations of such a memory device can include the insulator material being a SOD or a densified SOD. The spin-on dielectric can be positioned on a region of silicon nitride, where the region of silicon nitride can be positioned on an contacting a silicon substrate. Variations of such a memory device and its features can include a metal plate coupled to the set of the sets of memory cells and arranged opposite the digit line structured vertically and coupled to the set.

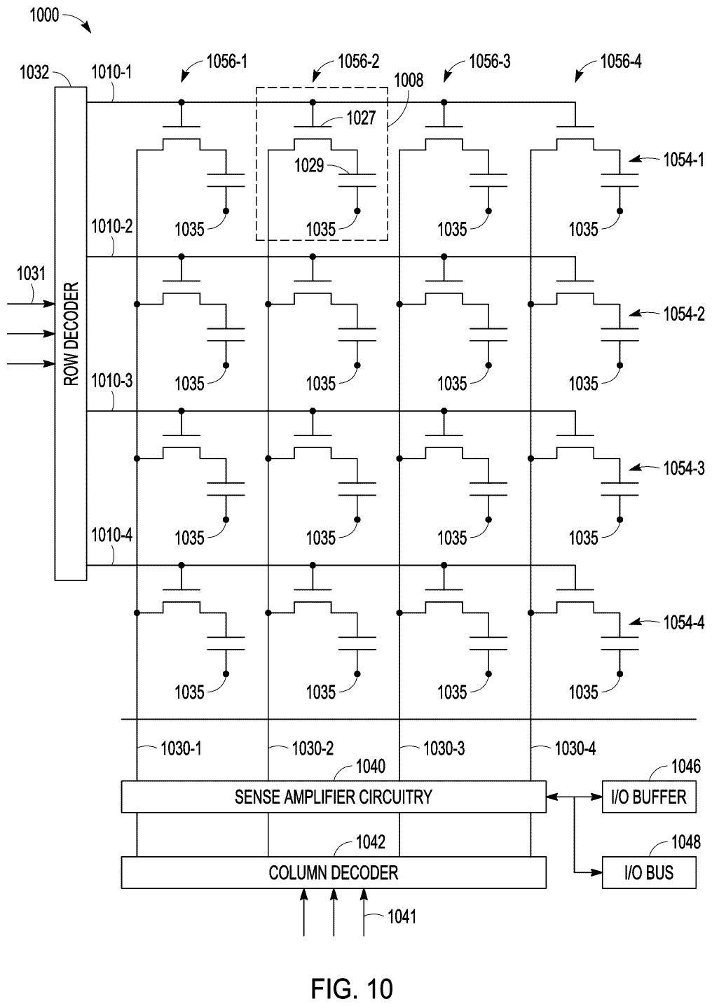

FIG. 10 is a schematic of circuitry of an embodiment of an example DRAM device 1000 that can include an architecture having a memory array with digit line or cell plate isolation that can be formed using the flow process associated with FIGS. 1-9 or variations thereof. The circuitry of FIG. 10 shows relative electrical connections among components of DRAM device 1000 that is applicable to a two-dimensional (2D) DRAM or a 3D-DRAM. DRAM device 1000 can include an array of memory cells 1008 (only one being labeled in FIG. 10 for ease of presentation) arranged in rows 1054-1, 1054-2, 1054-3, and 1054-4 and columns 1056-1, 1056-2, 1056-3, and 1056-4. Further, while only four rows 1054-1, 1054-2, 1054-3, and 1054-4 and four columns 1056-1, 1056-2, 1056-3, and 1056-4 of four memory cells are illustrated, DRAM devices, like DRAM device 1000, can have significantly more memory cells 1008 (e.g., tens, hundreds, or thousands of memory cells) per row or per column.

Each memory cell 1008 can include a single transistor 1027 and a single capacitor 1029, which is commonly referred to as a 1T1C (one-transistor-one capacitor cell). One plate of capacitor 1029, which can be termed the “node plate,” is connected to the drain terminal of transistor 1027, whereas the other plate of the capacitor 1029 is connected to a reference node 1035, which can be ground or other reference voltage node. Reference node 1035 can be a metal plate. Reference node 1035 can be common to a set of transistors 1027. A set of different metal plates can be implemented as reference nodes to different sets of transistors 1027. Each capacitor 1029 within the array of 1T1C memory cells 1008 typically serves to store one bit of data, and the respective transistor 1027 serves as an access device to write to or read from storage capacitor 1029.

The transistor gate terminals within each row of rows 1054-1, 1054-2, 1054-3, and 1054-4 are portions of respective access lines 1010-1, 1010-2, 1010-3, and 1010-4 (alternatively referred to as “word lines”), and the transistor source terminals within each of columns 1056-1, 1056-2, 1056-3, and 1056-4 are electrically connected to respective digit lines 1030-1, 1030-2, 1030-3, and 1030-4 (alternatively referred to as “bit lines”). A row decoder 1032 can selectively drive the individual access lines 1010-1, 1010-2, 1010-3, and 1010-4, responsive to row address signals 1031 input to row decoder 1032. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier (SA) circuitry 1040, which can transfer bit values between memory cells 1008 of the selected row of the rows 1054-1, 1054-2, 1054-3, and 1054-4 and input/output buffers 1046 (for write/read operations) or external input/output data buses 1048.

A column decoder 1042 responsive to column address signals 1041 can select which of the memory cells 1008 within the selected row is read out or written to. Alternatively, for read operations, the storage capacitors 1029 within the selected row can be read out simultaneously and latched, and the column decoder 1042 can then select which latch bits to connect to the output data bus 1048. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 1000 can be implemented as an integrated circuit within a package that includes pins for receiving supply voltages (e.g., to provide the source and gate voltages for the transistors 1027) and signals (including data, address, and control signals). FIG. 10 depicts DRAM device 1000 in simplified form to illustrate basic structural components, omitting many details of the memory cells 1008 and associated access lines 1010-1, 1010-2, 1010-3, and 1010-4 and digit lines 1030-1, 1030-2, 1030-3, and 1030-4 as well as the peripheral circuitry. For example, in addition to the row decoder 1032 and column decoder 1042, SA circuitry 1040, and buffers 1046, DRAM device 1000 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In 2D-DRAM arrays, the rows 1054-1, 1054-2, 1054-3, and 1054-4 and columns 1056-1, 1056-2, 1056-3, and 1056-4 of memory cells 1008 can be arranged along a single horizontal plane (i.e., a plane parallel to the layers) of the semiconductor substrate, e.g., in a rectangular lattice with mutually perpendicular horizontal access lines 1010-1, 1010-2, 1010-3, and 1010-4 and digit lines 1030-1, 1030-2, 1030-3, and 1030-4. In 3D-DRAM arrays, memory cells 1008 are arranged in a 3D lattice, for example as discussed with respect to FIGS. 1-9, that encompasses multiple vertically stacked horizontal planes corresponding to multiple tiers of memory cells 1008 whose transistor gate terminals are connected by horizontal access lines such as access lines 1010-1, 1010-2, 1010-3, and 1010-4. Digit lines 1030-1, 1030-2, 1030-3, and 1030-4 extend vertically through the memory array, and each of the digit lines 1030-1, 1030-2, 1030-3, and 1030-4 connects to the transistor source terminals of respective vertical columns 1056-1, 1056-2, 1056-3, and 1056-4 of associated memory cells 1008 at the multiple tiers. This 3D configuration of memory cells enables further increases in bit density compared with 2D arrays.

Though FIG. 10 provides an example of DRAM device 1000 that can include isolated digit lines and isolated metal plates as discussed with respect to FIGS. 1-9, other integrated circuits (ICs), including but not limited to other memory devices, can implement similar structures having isolation regions to digit lines and isolation regions to metal plates defined by the process taught herein, without etching out an entire layer of epitaxially grown regions for the memory cells, which can be used in a variety of electronic devices. Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices. These electronic devices provide examples of structures that can include isolation regions to digit lines and isolation regions to metal plates, defined by the process taught herein, within the electronic devices.

The following examples are example embodiments of methods, devices, and systems, in accordance with the teachings herein.

An example method 1 of forming a memory device can comprise forming a liner in a trench between formed memory cells, the liner formed on a bottom of the trench and along sidewalls of the trench; forming an insulator material on the liner, filling the trench; removing the insulator material to a level below a top surface of the memory cells, leaving a portion of the insulator material on the liner at the bottom of the trench and forming an opening that exposes the liner on the sidewalls; removing the liner from the sidewalls; and forming conductive material for a digit line on the portion of the insulator material and along the sidewalls.

An example method 2 of forming a memory device can include features of example method 1 of forming a memory device and can include removing the insulator material to the level below a top surface to include removing the insulator material to a top level of one or more dummy memory cell layers, the one or more dummy memory cell layers positioned below the memory cells stacked vertically.

An example method 3 of forming a memory device can include features of any of the preceding example methods of forming a memory device and can include the liner being a nitride liner.

An example method 4 of forming a memory device can include features of any of the preceding example methods of forming a memory device and can include the insulator material having a dielectric constant equal to or less than that of silicon dioxide.

An example method 5 of forming a memory device can include features of any of the preceding example methods of forming a memory device and can include the insulator material being a spin-on dielectric.

An example method 6 of forming a memory device can include features of example method 5 of forming a memory device and any of the preceding example methods of forming a memory device and can include densifying the spin-on dielectric.

An example method 7 of forming a memory device can include features of any of the preceding example methods of forming a memory device and can include removing the insulator material includes applying a wet etch, exposing the liner on the sidewalls.

An example method 8 of forming a memory device can include features of any of the preceding example methods of forming a memory device and can include forming one or more metals for the digit line on a dielectric region above the memory cells.

An example method 9 of forming a memory device can include features of any of the preceding example methods of forming a memory device and can include forming a metal for a metal plate to memory cells opposite the conductive material for the digit line.

In an example method 10 of forming a memory device, any of the example methods 1 to 9 of forming a memory device may be performed in forming an electronic apparatus further comprising a host processor and a communication bus extending between the host processor and the memory device.

In an example method 11 of forming a memory device, any of the example methods 1 to 10 of forming a memory device may be modified to include operations set forth in any other of example methods 1 to 10 of forming a memory device.

In an example method 12 of forming a memory device, any of the example methods 1 to 11 of forming a memory device may be implemented at least in part through use of instructions stored as a physical state in one or more machine-readable storage devices.

An example method 13 of forming a memory device can include features of any of the preceding example methods 1 to 12 of forming a memory device and can include performing functions associated with any features of example memory devices 1 to 12.

An example method 14 of forming a memory device can comprise forming a liner in a trench between formed memory cells, the liner formed on a bottom of the trench and along sidewalls of the trench; forming an insulator region on a portion of the liner at the bottom of the trench; removing the liner from the sidewalls; and forming metal for a digit line on the insulator region and along the sidewalls.

An example method 15 of forming a memory device can include features of example method 1 of forming a memory device and can include forming the insulator region to include seeded growth from the portion of the liner at the bottom of the trench.

An example method 16 of forming a memory device can include features of any of the preceding example methods of forming a memory device and can include forming a second metal for a metal plate to memory cells opposite the metal for the digit line.

In an example method 17 of forming a memory device, any of the example methods 14 to 15 of forming a memory device may be performed in forming an electronic apparatus further comprising a host processor and a communication bus extending between the host processor and the memory device.

In an example method 18 of forming a memory device, any of the example methods 14 to 17 of forming a memory device may be modified to include operations set forth in any other of example methods 14 to 17 of forming a memory device.

In an example method 19 of forming a memory device, any of the example methods 14 to 18 of forming a memory device may be implemented at least in part through use of instructions stored as a physical state in one or more machine-readable storage devices.

An example method 20 of forming a memory device can include features of any of the preceding example methods 14 to 19 of forming a memory device and can include performing functions associated with any features of example memory device 1 to 12 below.

An example memory device 1 can comprise an array of memory cells, the array including sets of memory cells arranged vertically; a digit line structured vertically and coupled to a set of the sets of memory cells arranged vertically; and an insulator material on which the digit line is positioned and contacts the insulator material, a top level of the insulator material being below a bottom level of the memory cells of the set corresponding to the digit line.

An example memory device 2 can include features of example memory device 1 and can include the set of memory cells arranged vertically coupled to the digit line to include eighty or more tiers of memory cells arranged vertically.

An example memory device 3 can include features of any of the preceding example memory devices and can include the memory cells of the set of memory cells arranged vertically coupled to the digit line is positioned on one or more levels of dummy cells.

An example memory device 4 can include features of example memory device 3 and any of the preceding example memory devices and can include the one or more levels of dummy cells providing a margin of approximately 160 nm of variation across a memory die on which the sets of memory cells are positioned.

An example memory device 5 can include features of any of the preceding example memory devices and can include the insulator material having a dielectric constant equal to or less than that of silicon dioxide.

An example memory device 6 can include features of any of the preceding example memory devices and can include the insulator material to include a spin-on dielectric.

An example memory device 7 can include features of example memory device 6 and any of the preceding example memory devices and can include the spin-on dielectric being positioned on a region of silicon nitride, the region of silicon nitride positioned on an contacting a silicon substrate.

An example memory device 8 can include features of example memory device 5 and any of the preceding example memory devices and can include the memory device to include a metal plate coupled to the set of the sets of memory cells and arranged opposite the digit line structured vertically and coupled to the set.

In an example memory device 9, any of the memory devices of example memory devices 1 to 8 may include memory devices incorporated into an electronic apparatus further comprising a host processor and a communication bus extending between the host processor and the memory device.

In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be operated in accordance with any of the below example methods 1 to 11 of forming a memory device or example methods 1 to 9 of forming a memory device.

An example machine-readable storage device storing instructions, that when executed by one or more processors, cause a machine to perform operations, can comprise instructions to perform functions associated with any features of example memory devices 1 to 12 or perform methods associated with any features of example methods 1 to 20 of forming a memory device. Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A method of forming a memory device, the method comprising:
forming a liner in a trench between formed memory cells, the liner formed on a bottom of the trench and along sidewalls of the trench;
forming an insulator material on the liner, filling the trench;
removing the insulator material to a level below a top surface of the memory cells, leaving a portion of the insulator material on the liner at the bottom of the trench and forming an opening that exposes the liner on the sidewalls;
removing the liner from the sidewalls; and
forming conductive material for a digit line on the portion of the insulator material and along the sidewalls.

2. The method of claim 1, wherein removing the insulator material to the level below a top surface includes removing the insulator material to a top level of one or more dummy memory cell layers, the one or more dummy memory cell layers positioned below the memory cells stacked vertically.

3. The method of claim 1, wherein the liner is a nitride liner.

4. The method of claim 1, wherein the insulator material has a dielectric constant equal to or less than that of silicon dioxide.

5. The method of claim 1, wherein the insulator material is a spin-on dielectric.

6. The method of claim 5, wherein the method includes densifying the spin-on dielectric.

7. The method of claim 1, wherein removing the insulator material includes applying a wet etch, exposing the liner on the sidewalls.

8. The method of claim 1, wherein forming the conductive material for the digit line includes forming one or more metals on a dielectric region above the memory cells.

9. The method of claim 1, wherein the method includes:
forming a metal for a metal plate to memory cells opposite the conductive material for the digit line.

10. A method of forming a memory device, the method comprising:
forming a liner in a trench between formed memory cells, the liner formed on a bottom of the trench and along sidewalls of the trench;
forming an insulator region on a portion of the liner at the bottom of the trench;
removing the liner from the sidewalls; and
forming metal for a digit line on the insulator region and along the sidewalls.

11. The method of claim 10, wherein forming the insulator region includes seeded growth from the portion of the liner at the bottom of the trench.

12. The method of claim 10, wherein the method includes forming a second metal for a metal plate to memory cells opposite the metal for the digit line.

13. A memory device comprising:
an array of memory cells, the array including sets of memory cells arranged vertically;
a digit line structured vertically and coupled to a set of the sets of memory cells arranged vertically; and
an insulator material on which the digit line is positioned and contacts the insulator material, a top level of the insulator material being below a bottom level of the memory cells of the set corresponding to the digit line.

14. The memory device of claim 13, wherein the set of memory cells arranged vertically coupled to the digit line includes eighty or more tiers of memory cells arranged vertically.

15. The memory device of claim 13, wherein the memory cells of the set of memory cells arranged vertically coupled to the digit line is positioned on one or more levels of dummy cells.

16. The memory device of claim 15, wherein the one or more levels of dummy cells provide a margin of approximately 160 nm of variation across a memory die on which the sets of memory cells are positioned.

17. The memory device of claim 13, wherein the insulator material has a dielectric constant equal to or less than that of silicon dioxide.

18. The memory device of claim 13, wherein the insulator material includes a spin-on dielectric.

19. The memory device of claim 18, wherein the spin-on dielectric is positioned on a region of silicon nitride, the region of silicon nitride positioned on a contacting a silicon substrate.

20. The memory device of claim 13, wherein the memory device includes a metal plate coupled to the set of the sets of memory cells and arranged opposite the digit line structured vertically and coupled to the set.
